(19) United States
(12) Patent Application Publication
(10) Pub. No.: US 2024/0079242 A1
(43) Pub. Date: Mar. 7, 2024

(54) SEMICONDUCTOR APPARATUS AND MANUFACTURING METHOD OF SEMICONDUCTOR APPARATUS

(71) Applicant: FUJI ELECTRIC CO., LTD., Kanagawa (JP)

(72) Inventors: Michiya KITANO, Matsumoto-city (JP); Tatsuya HASHIMOTO, Azumino-city (JP)

(21) Appl. No.: 18/356,230

(22) Filed: Jul. 21, 2023

(30) Foreign Application Priority Data
Sep. 1, 2022 (JP) 2022-139136

(51) Int. Cl. H01L 21/304; H01L 21/683

(52) U.S. Cl. CPC H01L 21/304; H01L 21/6836

(57) ABSTRACT

A manufacturing method of a semiconductor apparatus, including: preparing a wafer on which an adhesion layer is provided in an outer peripheral region of a front surface; applying a protective tape on the front surface of the wafer, wherein the protective tape is applied on the adhesion layer; cutting a front surface of the protective tape; and grinding a back surface of the wafer while holding the wafer by a grinding apparatus through the protective tape, is provided. In addition, a semiconductor apparatus, including: a wafer; a semiconductor device provided in a central region of a front surface of the wafer; and an adhesion layer of a polyimide film provided in an outer peripheral region surrounding the central region on the front surface of the wafer, is provided.

The contents of the following patent application(s) are incorporated herein by reference: NO. 2022-139136 filed in JP on Sep. 1, 2022

### BACKGROUND

### 1. Technical Field

The present invention relates to a semiconductor apparatus and a manufacturing method of the semiconductor apparatus.

### 2. Related Art

In Patent Document 1, it is described that “To provide a surface protective tape that allows an annular adhesive layer to be stuck only on a peripheral surplus region surrounding device regions of a wafer”. In Patent Document 2, it is described that “the protective tape cutting step in which the entire surface of the base material film of the protective tape stuck to the surface of the wafer is cut with a cutting tool 28 to the extent that this does not reach the adhesive material layer, thereby forming a flat surface”.

### PRIOR ART DOCUMENTS

### Patent Documents

Patent Document 1: Japanese Patent Application Publication No. 2013-243310
Patent Document 2: Japanese Patent Application Publication No. 2013-21017

### BRIEF DESCRIPTION OF THE DRAWINGS

FIG. 1 is a diagram for explaining an example of a manufacturing method of a semiconductor apparatus 100.

FIG. 2 is a diagram for explaining an example of the manufacturing method of the semiconductor apparatus 100.

FIG. 3A illustrates an example of a cross-sectional view of a wafer 1 after steps S110 to S160 are finished.

FIG. 3B illustrates an example of a cross-sectional view of the wafer 1 after steps S110 to S160 are finished.

FIG. 3C illustrates an example of a top view of the wafer 1 on which an adhesion layer 140 of a polyimide film is provided.

FIG. 3D illustrates an example of a top view of the wafer 1 on which an adhesion layer 140 of a polyimide film is provided.

FIG. 3E illustrates an example of a top view of the wafer 1 on which an adhesion layer 140 of a resist is provided.

FIG. 4 illustrates an example of a cross-sectional view of the wafer 1 on which a protective tape 120 is applied.

FIG. 5A illustrates an example of a cross-sectional view of the wafer 1 at the start of a protective tape cutting step S180.

FIG. 5B illustrates an example of a cross-sectional view of the wafer 1 during execution of the protective tape cutting step S180.

FIG. 5C illustrates an example of a top view of a cutting apparatus 130 in the protective tape cutting step S180.

FIG. 5D illustrates an example of a cross-sectional view of the wafer 1 after completion of the protective tape cutting step S180.

FIG. 6A illustrates an example of a cross-sectional view of the wafer 1 at the start of a back surface grinding step S210.

FIG. 6B illustrates an example of a cross-sectional view of the wafer 1 after completion of the back surface grinding step S210.

FIG. 7 illustrates an example of a cross-sectional view of the wafer 1 after the protective tape 120 is removed.

FIG. 8 illustrates an example of a cross-sectional view of a wafer 1 in a protective tape cutting step in a manufacturing method in a semiconductor manufacturing according to a comparative example.

### DESCRIPTION OF EXEMPLARY EMBODIMENTS

Hereinafter, embodiments of the present invention will be described, but the embodiments do not limit the invention according to the claims. In addition, not all of the combinations of features described in the embodiments are essential to the solution of the invention. Note that, in the present specification and drawings, the elements having substantially the same functions and configurations are denoted with the same reference signs, and the overlapping descriptions thereof are omitted. In addition, the elements that are not directly relevant to the present invention are not shown. In one drawing, elements having the same function and configuration are representatively denoted by a reference sign, and the reference signs for the others may be omitted.

As used herein, one side in a direction parallel to a depth direction of a semiconductor substrate is referred to as “upper” and the other side is referred to as “lower”. One surface of two principal surfaces of a substrate, a layer, or other member is referred to as a front surface, and the other surface is referred to as a back surface. The “upper” and “lower” directions are not limited to a gravity direction or a direction at a time of mounting a semiconductor module.

As used herein, technical matters may be described with orthogonal coordinate axes consisting of an X axis, a Y axis, and a Z axis. The orthogonal coordinate axes are merely for specifying relative positions of components, and are thus not for limiting to a specific direction. For example, the Z axis is not limited to represent a height direction with respect to the ground. Note that a +Z axis direction and a −Z axis direction are directions opposite to each other. When a direction is referred to as a “Z axis direction” without these “+” and “−” signs, it means the Z axis direction is parallel to +Z and −Z axes. As used herein, orthogonal axes parallel to the front surface and the back surface of the semiconductor substrate are referred to as an X axis and a Y axis. In addition, an axis perpendicular to the front surface and the back surface of the semiconductor substrate is referred to as the Z axis. As used herein, a direction of the Z axis may be referred to as a depth direction. Further, as used herein, a direction parallel to the front surface and the back surface of the semiconductor substrate, including an X axis and a Y axis, may be referred to as a horizontal direction.

As used herein, phrases such as “same” or “equal” may be used even when there is an error caused due to a variation in a fabrication step or the like. This error is within a range of 10% or less, for example.

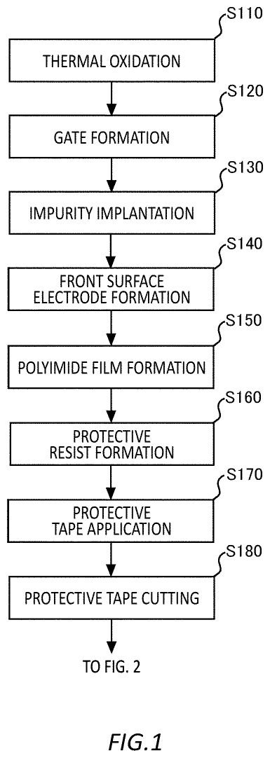

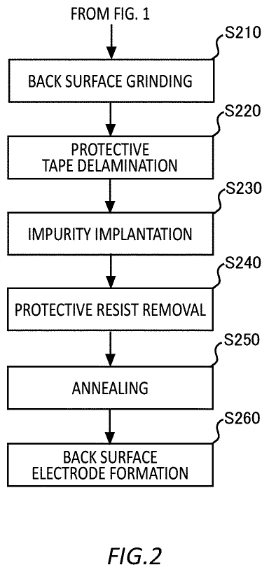

FIGS. 1 and 2 are drawings for explaining examples of a manufacturing method of a semiconductor apparatus 100. FIG. 1 illustrates steps executed on a front surface of a wafer, and FIG. 2 illustrates steps executed on a back surface of the wafer. Here, a back surface grinding step of the wafer and its related steps will be mainly described, and therefore descriptions for other steps are simplified or omitted.

A back surface grinding step of a wafer is a step for grinding and thinning a back surface of the wafer, which is an important step for improving characteristics of a semiconductor apparatus. In order to protect the wafer from damage during the back surface grinding step, a protective tape is applied on a front surface of the wafer prior to the back surface grinding step.

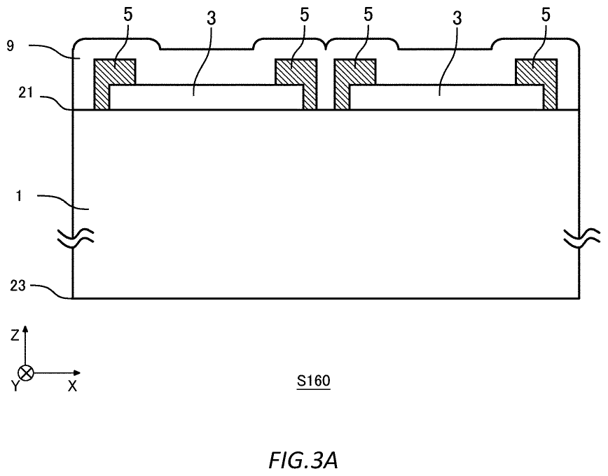

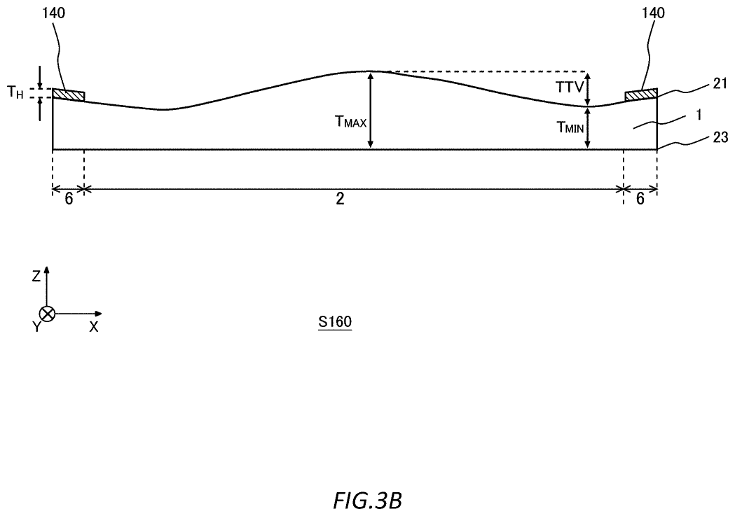

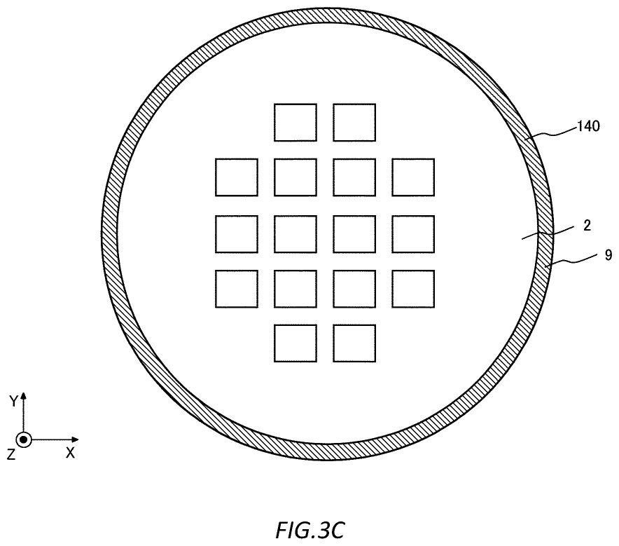

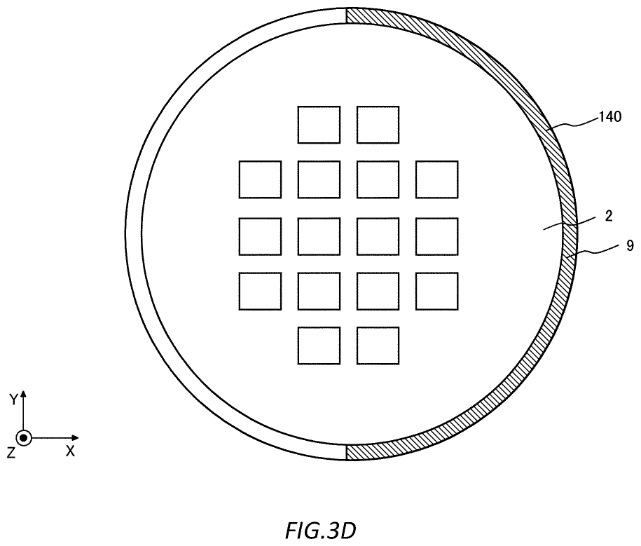

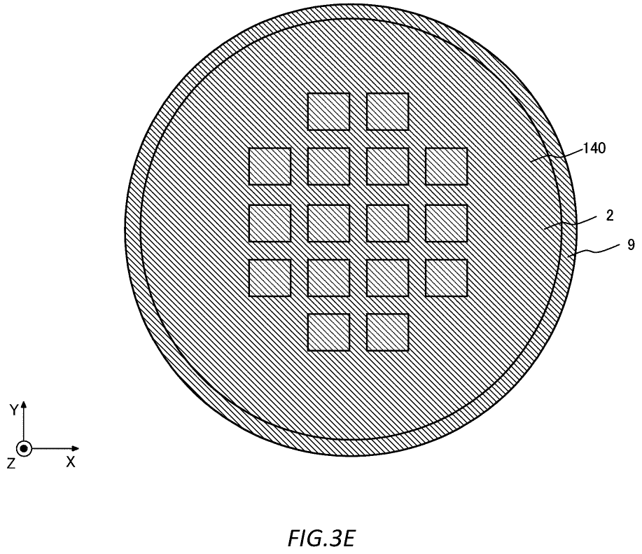

The manufacturing method of the semiconductor apparatus 100 will be described by referring to FIGS. 3A to 7 as appropriate, in conjunction with FIGS. 1 and 2.

The semiconductor apparatus 100 includes a wafer 1. The wafer 1 in the present example is a silicon substrate having an approximately circular shape in a top view. A plurality of regions are formed on the wafer 1, which become chips when cut out. By way of example, a diameter of the wafer 1 is 200±5 mm or 300 mm±5 mm, but the value of the diameter is not limited to this.

Note that, as used herein, the term “semiconductor apparatus” may mean a chip, or a wafer on which a plurality of chips are formed. The semiconductor apparatus 100 may include a diode such as an insulated gate bipolar transistor (IGBT), FWD (Free Wheel Diode) and RC (Reverse Conducting)—IGBT provided by combining the two, and a MOS transistor or the like.

The manufacturing method of the semiconductor apparatus 100 includes: a thermal oxidation step S110; a gate formation step S120; an impurity implantation step S130; a front surface electrode formation step S140; a polyimide film formation step S150; a protective resist formation step S160; a protective tape application step S170; a protective tape cutting step S180; a back surface grinding step S210; a protective tape delamination step S220; an impurity implantation step S230; a protective resist removal step S240; an annealing step S250; and a back surface electrode formation step S260.

In the thermal oxidation step S110, an oxide film is formed on a front surface of the wafer 1 by thermally oxidizing the wafer 1 by exposing it to high-temperature oxygen. This oxide film can be partially removed by etching or the like. In the gate formation step S120, a gate is formed by etching the front surface of the wafer 1 to form a gate trench, forming a gate insulating film by depositing an oxide film or a nitride film on an inner wall of the gate trench, and then embedding an area farther inward than the gate insulating film with impurity-doped polysilicon etc.

In the impurity implantation step S130, impurities are ion implanted into a predetermined region from a front surface 21 of the wafer 1 by using a resist mask. In the front surface electrode formation step S140, a front surface electrode 3, a wire, or the like is formed on the front surface 21 of the wafer 1. These steps form front surface device structure of a semiconductor device such as a transistor on the wafer 1.

Next, in the polyimide film formation step S150, a polyimide film which protects the front surface device structure is formed on the front surface 21 of the wafer 1. The polyimide film formation step S150 includes: a step for coating polyimide on the front surface 21 of the wafer 1; a step for removing the polyimide that has spread to the vicinity of an outer peripheral edge and the back surface 23 of the wafer by edge rinsing processing; and a step for curing the polyimide coated on a central region 2. Note that, the manufacturing method of the semiconductor apparatus 100 may include, instead of the steps S110 to S150, a step for preparing a wafer 1 that has undergone the same steps as the steps S110 to S150.

Next, in the protective resist formation step S160, a protective resist 9 is formed on the polyimide film 5. The protective resist 9 protects the front surface device structure from contamination and breakage during the following impurity implantation step S230. The protective resist 9 is formed in the following manner. Resist is dispensed to spin coat the front surface 21 of the wafer 1, and then the resist is dissolved and removed in a region where the protective resist 9 is not to be provided by edge rinsing processing using an organic solvent. Alternatively, the protective resist 9 can be formed in the following manner. Photosensitive resist spin coated on the front surface 21 of the wafer 1 is exposed or non-exposed to lights, and then the resist is removed in a region where the protective resist 9 is not to be provided by developer.

FIGS. 3A and 3B illustrate examples of cross-sectional views of the wafer 1 after the steps S110 to S160 are finished. FIG. 3A is an enlarged cross-sectional view of a central region 2 of the wafer 1 on which a plurality of chips are formed, and FIG. 3B is a schematic cross-sectional view of the entire wafer 1. The wafer has the central region 2 on which the plurality of chips are formed, and an outer peripheral region 6 which surrounds the central region 2. In an example, a width of the outer peripheral region 6 is 2 mm or more, and 6 mm or less.

FIG. 3A illustrates front surface electrodes 3 provided on the front surface device structure, polyimide films 5 provided in direct contact with the front surface electrodes 3 and the front surface 21 of the wafer 1, and the protective resist 9 provided covering them.

Each front surface electrode 3 is provided corresponding to an impurity implantation region which is unillustrated. A polyimide film 5 is separated from a polyimide film 5 provide on adjacent front surface device structure. The polyimide films 5 have an opening that exposes at least a part of the front surface electrode 3. The protective resist 9 is provided covering at least the entire central region 2 of the wafer 1 in a top view.

As can be seen from FIG. 3A, in the central region 2 of the wafer 1, providing the front surface electrodes 3 or the polyimide films 5, or both of them on the front surface 21 of the wafer 1 causes an upper surface of the protective resist 9 that covers the above structure to be uneven. Also, the front surface 21 itself of the wafer 1 is uneven, but it is omitted from illustration in FIG. 3A.

FIG. 3B illustrates the central region 2 on which the plurality of chips are formed, and the outer peripheral region 6 surrounding the central region 2 in the wafer 1. In FIG. 3B and subsequent drawings, for a purpose of simplification, structure such as the front surface electrode 3 provided on the front surface 21 of the wafer 1 is omitted and the unevenness caused by the above structure and the unevenness of the front surface 21 itself of the wafer 1 are illustrated together as unevenness of the front surface 21 of the wafer 1. The number of uneven parts illustrated is merely an example, and the scale for the uneven parts differs from the actual scale.

In a thickness direction (Z axis direction) of the wafer 1, a difference between a maximum thickness value T_{MAX} and a minimum thickness value T_{MIN} with reference to the back surface 23 of the wafer 1 is called Total Thickness Variation (TTV). In an example, the TTV of the wafer 1 is 10 lam or less.

The manufacturing method of the semiconductor apparatus 100 according to the present example includes a step for forming an adhesion layer 140 in the outer peripheral region 6. Adhesive strength of a protective tape applied in the protective tape application step S170 to be described below to the adhesion layer 140 is greater than adhesive strength of the protective tape to the wafer 1. That is, compared to a case in which the adhesion layer 140 is not provided in the outer peripheral region 6, the protective tape 120 adheres more firmly to the front surface 21 of the wafer 1 through the adhesion layer 140 in the semiconductor apparatus 100 of the present example. Alternatively, the manufacturing method of the semiconductor apparatus 100 may include, instead of the step for forming the adhesion layer 140 in the outer peripheral region 6, a step for preparing a wafer 1 on which an adhesion layer 140 is provided in an outer peripheral region 6.

A thickness of the adhesion layer 140 in a thickness direction (Z axis direction) of the wafer is greater than 0 μm, and 20 μm or less. The thickness of the adhesion layer 140 may be a TTV or less. The thickness of the adhesion layer 140 can also be 10 μm or less. With such a thickness range, increase in TTV of the wafer 1 due to the formation of the adhesion layer 140 is restrained, and influence on thickness accuracy in a process in the back surface grinding step S210 is prevented.

The adhesion layer 140 in the present example is an organic thin film. The inventors of the present application investigated that the organic thin film had good adhesion to the protective tape 120. In an example, the adhesion layer 140 is a polyimide film. In this case, the adhesion layer 140 may be formed by the same process as the polyimide film 5 to be provided in the central region 2 in the polyimide film formation step S150. That is, in the polyimide film formation step S150, the adhesion layer 140 may be formed in the outer peripheral region 6 by adjusting a range of the polyimide film 5 to be removed in the edge rinsing processing. In an example, if an adhesion layer 140 of a polyimide film is to be formed, a range in which polyimide is removed in edge rinsing processing is within a range of from 3 mm to 7 mm, inclusive, from an outer peripheral edge of a wafer 1. In this manner, on a front surface 21 of the wafer 1, an outer peripheral edge of the adhesion layer 140 is positioned farther inward than an outer peripheral edge of the wafer 1, and thereby the polyimide is prevented from spreading to a back surface 23 of the wafer 1.

FIGS. 3C and 3D illustrate examples of top views of wafers 1 on which adhesion layers 140 of polyimide films are provided. In FIGS. 3C and 3D, regions in which the adhesion layers 140 are provided are shown by oblique hatching. Note that, in FIGS. 3C and 3D, for a purpose of simplification, polyimide films 5 provided in central regions 2 are omitted.

The adhesion layer 140 of the present example is formed over at least half the circumference of the wafer in the outer peripheral region 6. The adhesion layer 140 in FIG. 3C is formed over the entire circumference of the wafer in the outer peripheral region 6, and the adhesion layer 140 in FIG. 3D is formed over half the circumference of the wafer in the outer peripheral region 6. The adhesion layers 140 are formed in regions within the outer peripheral regions 6, at least where cutting tools enter in the protective tape cutting step S180 to be described below.

The adhesion layer 140 of the present example may be separated from the polyimide film 5. In order to prevent delamination of the protective tape 120, it is desirable to provide the adhesion layer 140 as close to the outer peripheral edge of the wafer 1 as possible. However, if the adhesion layer 140 is too close to the outer peripheral edge of the wafer 1, there is a risk that the adhesion layer 140 may spread to a side of the back surface 23 of the wafer 1. Therefore, by specifying a distance between the adhesion layer 140 and the outer peripheral edge of the wafer 1 within the above-described range, delamination of the protective tape 120 can be prevented while preventing the adhesion layer 140 from spreading to the side of the back surface 23 of the wafer 1. In an example, the adhesion layer 140 is provided in a range of between 3 mm or more and 4 mm or less from the outer peripheral edge of the wafer 1. Note that, for such reasons as step convenience, the adhesion layer 140 can be provided outside this range.

Alternatively, the adhesion layer 140 can be a resist. In an example, the adhesion layer 140 is the resist. In this case, the adhesion layer 140 may be formed in the same process as the protective resist 9 to be provided on the polyimide film 5 in the central region 2 in the protective resist formation step S160. That is, in the protective resist formation step S160, the adhesion layer 140 may be formed in the outer peripheral region 6 by adjusting a range of the protective resist 9 to be removed in the edge rinsing processing. In an example, if an adhesion layer 140 of a resist is to be formed, a range in which the resist is removed in edge rinsing processing is within a range of from 2 mm to 6 mm, inclusive, from an outer peripheral edge of a wafer 1. In this manner, on a front surface 21 of the wafer 1, an outer peripheral edge of the adhesion layer 140 is positioned farther inward than an outer peripheral edge of the wafer 1, and thereby the resist is prevented from spreading to a back surface 23 of the wafer 1.

FIG. 3E illustrates an example of a top view of the wafer 1 on which the adhesion layer 140 of the resist is provided. In FIG. 3E, a region in which the adhesion layer 140 is provided is shown by oblique hatching. The adhesion layer 140 of the present example is formed over the entire central region 2, and at least a part of the outer peripheral region 6. That is, in the present example, the protective resist 9 also serves as the adhesion layer 140.

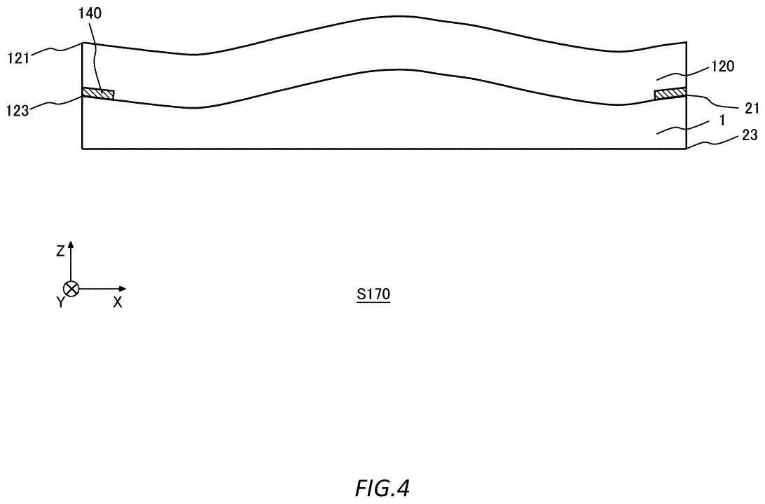

Next, in the protective tape application step S170, a protective tape 120 is applied on the front surface 21 of the wafer 1. FIG. 4 illustrates an example of a cross-sectional view of the wafer 1 on which the protective tape 120 is applied. The protective tape is generally referred to as a back-grinding (BG) tape. The protective tape 120 has a front surface 121 and a back surface 123. The protective tape 120 is applied to the front surface 21 of the wafer 1 so that its back surface 123 is in direct contact with the adhesion layer 140. The protective tape 120 protects the front surface device structure from contamination and breakage in the back surface grinding step S210 to be described below.

In an example, the protective tape 120 has structure formed of a base material and adhesive laminated together. A diameter of the protective tape 120 may be larger than a diameter of the wafer. A thickness of the protective tape 120 is from 100 μm to 300 μm. The protective tape 120 may cover the entire surface of the front surface 21. The front surface 121 of the applied protective tape 120 becomes uneven in accordance with the unevenness of the front surface 21 of the wafer 1.

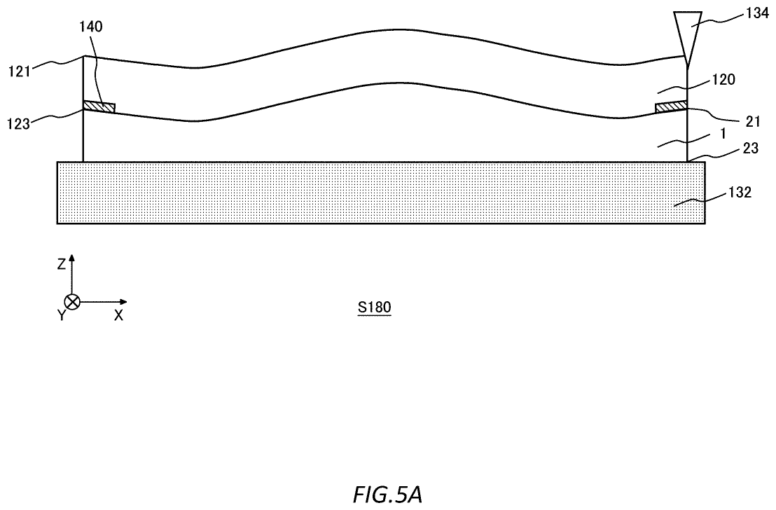

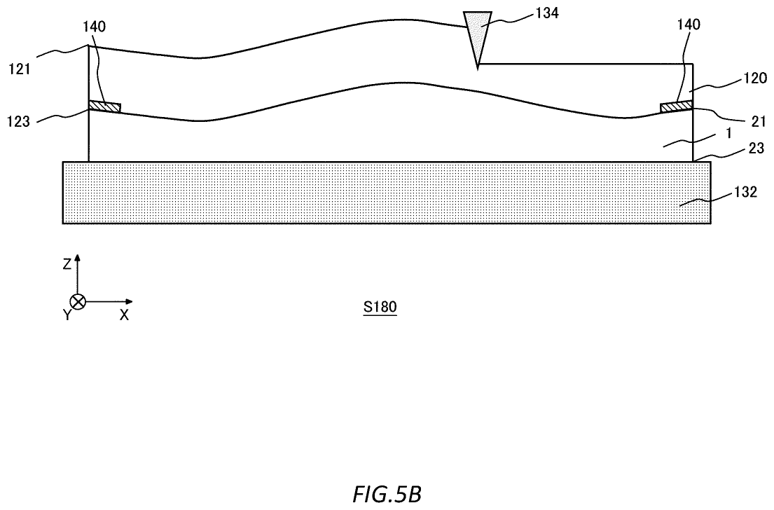

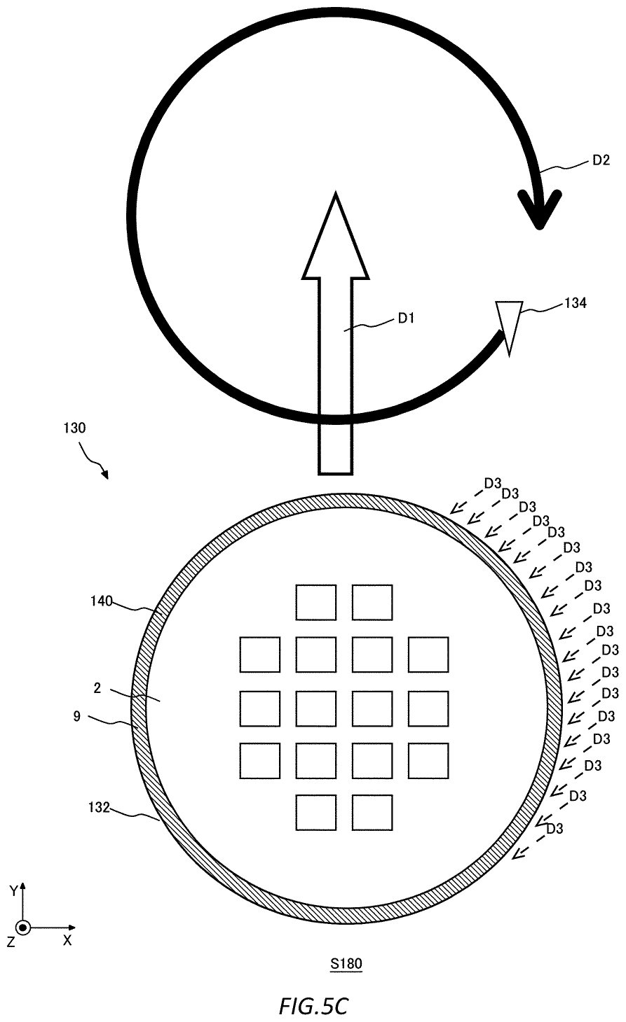

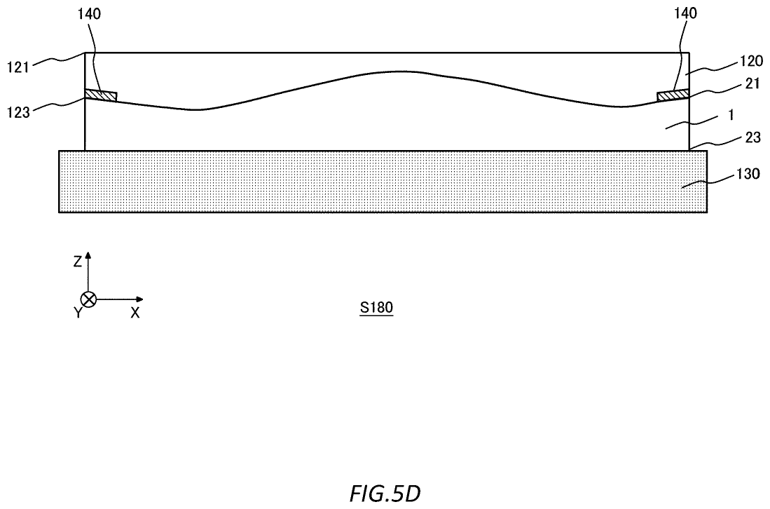

Next, in the protective tape cutting step S180, the front surface 121 of the protective tape 120 is cut. FIG. 5A illustrates an example of a cross-sectional view of the wafer 1 at the start of the protective tape cutting step S180. FIG. 58 illustrates an example of a cross-sectional view of the wafer 1 during execution of the protective tape cutting step S180. FIG. 5C illustrates an example of a top view of a cutting apparatus 130 in the protective tape cutting step S180. FIG. 5D illustrates an example of a cross-sectional view of the wafer 1 after completion of the protective tape cutting step S180.

The cutting apparatus 130 has a table 132 and a cutting tool 134. The table 132 is a stand on which a wafer is placed and supported, and in an example, is a chuck table. The wafer is supported on the table 132 through the back surface 23 of the wafer 1. The cutting tool 134 is a tool with a cutting edge, and in an example, a diamond cutting tool. The cutting tool 134 rotates at high speed on a plane parallel to an upper surface of the table 132 (i.e., XY plane) in a rotational direction D2.

Table 132 moves in a table movement direction D1 (i.e., Y axis direction) while supporting the back surface 23 of the wafer 1, and is arranged below the cutting tool 134, which rotates at a high speed. When the table 132 is arranged below the cutting tool 134, the cutting edge of the cutting tool 134 enters above the wafer in an entry direction D3 and contacts the protective tape 120, then cuts the protective tape 120 along the rotational direction D2. In an example, a cutting thickness of the protective tape 120 is 10 μm or more, and 50 μm or less from the front surface 121 of the protective tape 120.

Note that, while FIG. 5C shows an example of using the wafer on which the adhesion layer 140 is provided over the entire circumference of the outer peripheral region 6 (i.e., that of FIG. 3C), it is not limited to this example. The wafers shown in FIGS. 3D and 3E can also be used.

The front surface 121 of the protective tape 120 is flattened by the table 132 repeatedly moving in the table movement direction D1 and in its opposite direction below the cutting tool 134, which rotates at a high speed. in this manner, a distance from the back surface 23 of the wafer 1 to the front surface 121 of the protective tape 120 becomes uniform, as shown in FIG. 5D.

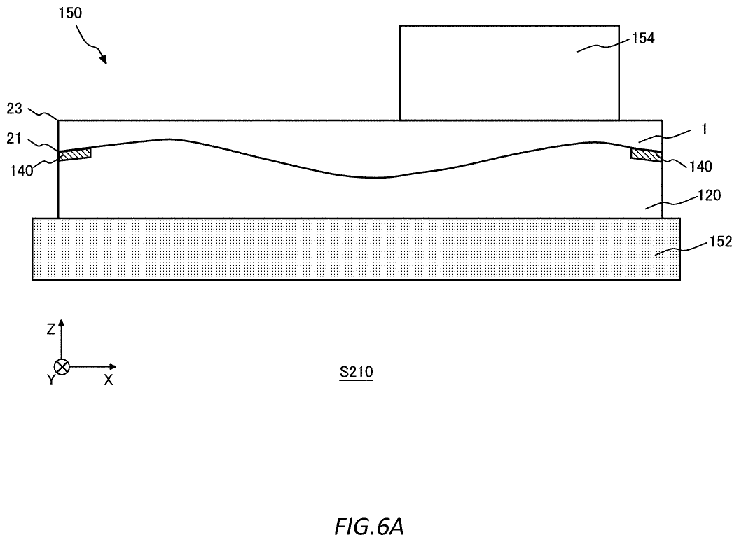

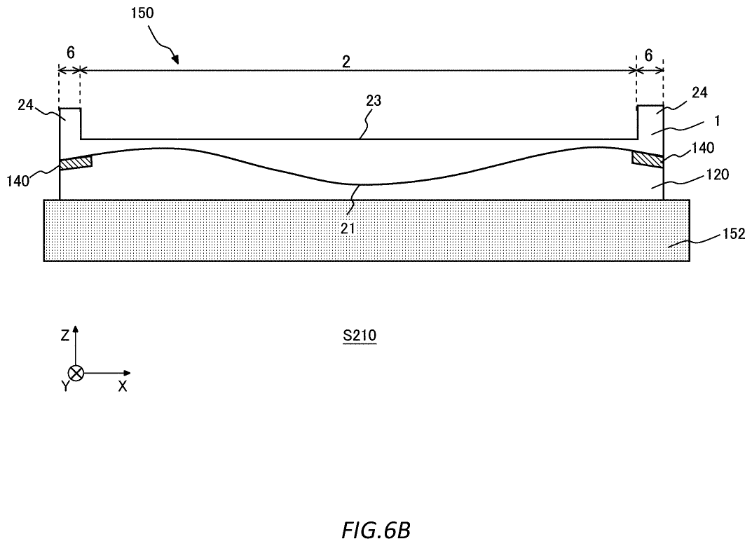

Next, in the back surface grinding step S210, the wafer is held by the grinding apparatus 150 through the protective tape 120, and then the back surface 23 of the wafer 1 is ground. FIG. 6A illustrates an example of a cross-sectional view of the wafer 1 at the start of the back surface grinding step S210. FIG. 6B illustrates an example of a cross-sectional view of the wafer 1 after completion of the back surface grinding step S210.

The grinding apparatus 150 has a table 152 and a whetstone 154. The table 152 is a stand on which a wafer is placed and supported, and in an example, is a chuck table. The wafer is supported on the table 152 through the flattened front surface 121 of the protective tape 120. The whetstone 154 grinds the back surface 23 of the wafer 1 supported on the table 152.

In the back surface grinding step S210, a distance from the back surface 23 of the wafer 1 to the front surface 121 of the protective tape 120 becomes uniform, and the back surface 23 of the wafer 1 is flattened. The back surface grinding step S210 may include a step of etching the back surface 23 of the ground wafer 1 in order to remove process distortion.

Conventionally, the back surface grinding step is performed by supporting a protective tape on a table while leaving unevenness of a front surface of the protective tape. Therefore, in the back surface grinding step, even if a distance from the table to a back surface of a semiconductor substrate is made uniform, the unevenness of the front surface of the protective tape is sometimes reflected in a thickness of the semiconductor substrate, which causes unevenness on the back surface of the semiconductor substrate after the back surface grinding step.

In contrast, in the present example, the protective tape cutting step S180 is performed before the back surface grinding step S210, and the table 152 supports the flattened front surface 121 of the protective tape 120, so that the distance from the table 152 to the back surface 23 of the wafer 1 is made uniform and the back surface 23 of the wafer 1 can be flattened.

As shown in FIG. 6B, in the back surface grinding step S210, the whetstone 154 grinds the back surface 23 while leaving the outer peripheral region 6, so that a convex portion 24 protruding from the back surface 23 may be formed over the outer peripheral region 6 along the entire outer peripheral edge of the wafer. By providing the convex portion 24, warpage of the wafer is reduced and its strength is improved, which makes it easier to handle the wafer and enables the wafer to be made even thinner.

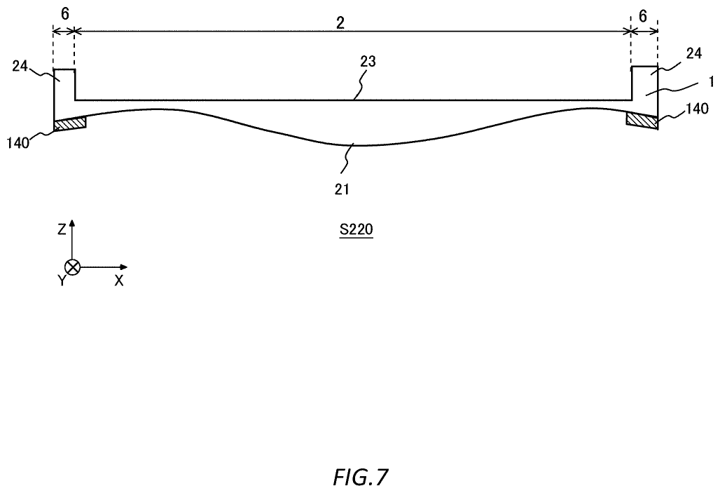

Next, in the protective tape delamination step S220, the protective tape 120 is removed by delamination. FIG. 7 illustrates an example of a cross-sectional view of the wafer 1 after the protective tape 120 is removed. By removing the protective tape 120 immediately after the back surface grinding step S210 is finished, dirt, shavings, etc. adhered to the protective tape 120 in the back surface grinding step S210 can be removed, and the subsequent steps can proceed smoothly.

Next, in the impurity implantation step S230, impurities are ion implanted into a predetermined region from the back surface 23 of wafer 1 by using a resist mask. In the protective resist removal step S240, the protective resist 9 provided on the front surface 21 of the wafer 1 is removed. Examples of removing means are as described for the protective resist formation step S160, and thus description thereof is omitted here. If the adhesion layer 140 provided in the outer peripheral region 6 of the front surface 21 is a resist, the adhesion layer 140 may be removed together.

In the annealing step S250, impurities implanted in the impurity implantation step S130 and the impurity implantation step S230 are activated and diffuse. In the back surface electrode formation step S260, a back surface electrode, a wire, or the like is formed under the back surface 23 of the wafer 1. These steps form back surface device structure of a semiconductor device such as a transistor on the wafer 1.

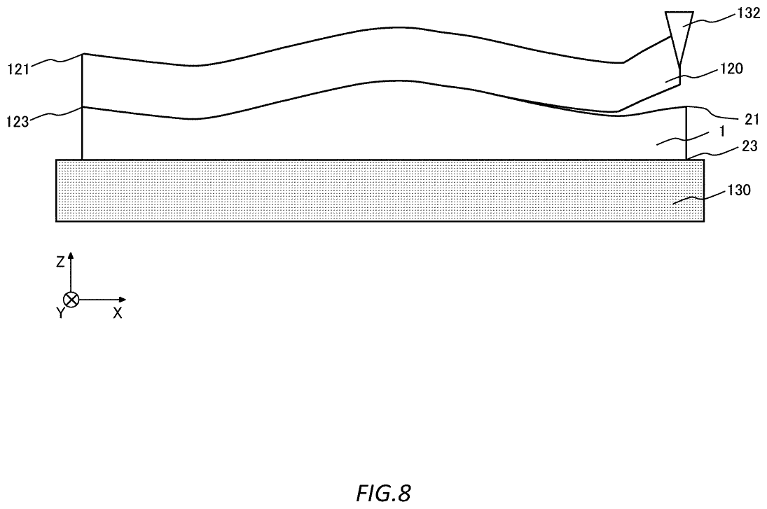

FIG. 8 illustrates an example of a cross-sectional view of a wafer 1 in a protective tape cutting step in a manufacturing method in a semiconductor manufacturing according to a comparative example. The manufacturing method in the semiconductor manufacturing according to the comparative example does not include a step for forming an adhesion layer in an outer peripheral region of a front surface of the wafer. Other steps in the comparative example are the same as the manufacturing method in the semiconductor manufacturing according to the present example, so the description thereof will be omitted.

Conventionally, when a cutting tool 134 enters in the protective tape cutting step, the cutting tool 134 that contacts an outer peripheral edge of a protective tape 120 sometimes cause delamination of the protective tape 120 from a front surface 21 of the wafer 1. The cause of this can be attributed to the cutting tool 134 having a dulled cutting edge, adhesive strength of the protective tape 120 being weak, and so on. If the protective tape 120 is delaminated, the protective tape application step must be redone or the wafer itself must be discarded, which increases costs or lowers yields.

In order to prevent the protective tape 120 from being delaminated, it is considered to use a tape with greater adhesive strength than a commonly used protective tape, but there is a risk that the protective tape will not to be delaminated and thus damage the wafer in the protective tape delamination step after the back surface grinding step.

In the manufacturing method in the semiconductor manufacturing according to the present example, by preparing a wafer on which the adhesion layer 140 is provided in the outer peripheral region 6 of the front surface 21, adhesion between the protective tape 120 and the wafer 1 is improved, and thus delamination of the protective tape 120 in the protective tape cutting step S180 can be prevented.

The adhesion layer 140 can be formed in the same step as the conventional step of forming a front surface device structure, i.e., the polyimide film formation step S150 or the protective resist formation step S160, so that no additional process is required. Therefore, compared to a case in which a protective tape with strong adhesive strength is used, cost increase can be restrained.

In addition, as shown in FIG. 3C, if an adhesion layer 140 of a polyimide film is provided only in an outer peripheral region 6, because adhesive strength of a protective tape 120 to the region in which the adhesion layer 140 is not provided (e.g., central region 2) is smaller than adhesive strength of the protective tape 120 to the adhesion layer 140, the protective tape 120 can be easily delaminated after the back surface grinding step S210, thus further cost reduction is possible by improving throughput of the protective tape delamination step S220.

Further, as shown in FIG. 3D, if an adhesion layer 140 of a polyimide film is provided only in a part of an outer peripheral region 6, because the region in which the adhesive strength of the protective tape 120 is increased is even more limited, the protective tape 120 can be delaminated even more easily after the back surface grinding step S210, thus further cost reduction is possible.

While the present invention has been described by way of the embodiments above, the technical scope of the present invention is not limited to the above described embodiments. It is apparent to persons skilled in the art that various alterations or improvements can be made to the above described embodiments. It is also apparent from the description of the claims that the embodiments to which such alterations or improvements are made can be included in the technical scope of the present invention.

The operations, procedures, steps, stages, etc. of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

1: wafer; 2: central region; 3: front surface electrode; 5: polyimide film; 6: outer peripheral region; 9: protective resist; 21: front surface; 23: back surface; 24: convex portion; 120: protective tape; 121: front surface; 123: back surface; 100: semiconductor apparatus; 130: cutting apparatus; 132: table; 134: cutting tool; 140: adhesion layer; 150: grinding apparatus; 152: table; 154: whetstone.

What is claimed is:

1. A manufacturing method of a semiconductor apparatus, comprising:
preparing a wafer on which an adhesion layer is provided in an outer peripheral region of a front surface;
applying a protective tape on the front surface of the wafer, wherein the protective tape is applied on the adhesion layer;
cutting a front surface of the protective tape; and
grinding a back surface of the wafer while holding the wafer by a grinding apparatus through the protective tape.

2. The manufacturing method of the semiconductor apparatus according to claim 1, wherein
the outer peripheral region is a region surrounding a central region in which a semiconductor device is provided on the front surface of the wafer.

3. The manufacturing method of the semiconductor apparatus according to claim 2, wherein
a width of the outer peripheral region is 2 mm or more and 6 mm or less.

4. The manufacturing method of the semiconductor apparatus according to claim 2, wherein
on the front surface of the wafer, an outer peripheral edge of the adhesion layer is farther inward than an outer peripheral edge of the wafer.

5. The manufacturing method of the semiconductor apparatus according to claim 3, wherein
on the front surface of the wafer, an outer peripheral edge of the adhesion layer is farther inward than an outer peripheral edge of the wafer.

6. The manufacturing method of the semiconductor apparatus according to claim 4, wherein
the adhesion layer is provided in a range of between 3 mm or more and 4 mm or less from the outer peripheral edge of the wafer.

7. The manufacturing method of the semiconductor apparatus according to claim 1, wherein
adhesive strength of the protective tape to the adhesion layer is greater than adhesive strength of the protective tape to the wafer.

8. The manufacturing method of the semiconductor apparatus according to claim 1, wherein
the adhesion layer is an organic thin film.

9. The manufacturing method of the semiconductor apparatus according to claim 1, wherein
the adhesion layer is a resist.

10. The manufacturing method of the semiconductor apparatus according to claim 1, wherein
the adhesion layer is a polyimide film.

11. The manufacturing method of the semiconductor apparatus according to claim 10, wherein
the preparing the wafer has forming the adhesion layer on at least half a circumference of the wafer in the outer peripheral region.

12. The manufacturing method of the semiconductor apparatus according to claim 1, wherein
the preparing the wafer has forming the adhesion layer on an entire circumference of the wafer in the outer peripheral region.

13. The manufacturing method of the semiconductor apparatus according to claim 1, wherein
a thickness of the adhesion layer is greater than 0 μm, and 20 μm or less.

14. The manufacturing method of the semiconductor apparatus according to claim 1, comprising,
after the grinding the back surface of the wafer, removing the protective tape.

15. A semiconductor apparatus, comprising:
a wafer;
a semiconductor device provided in a central region of a front surface of the wafer; and
an adhesion layer of a polyimide film provided in an outer peripheral region surrounding the central region on the front surface of the wafer.

16. The semiconductor apparatus according to claim 15, wherein
the adhesion layer is provided on at least half a circumference of the wafer in the outer peripheral region.

17. The semiconductor apparatus according to claim 16, wherein
the adhesion layer is provided on an entire circumference of the wafer in the outer peripheral region.

18. The semiconductor apparatus according to claim 15, wherein
the adhesion layer is provided in a range of between 3 mm or more and 4 mm or less from an outer peripheral edge of the wafer.

19. The semiconductor apparatus according to claim 15, wherein
a thickness of the adhesion layer is greater than 0 μm, and 20 μm or less.
